(19) United States
(12) Patent Application Publication
(10) Pub. No.: US 2013/0160823 A1
(43) Pub. Date: Jun. 27, 2013

(54) INTEGRATED STRUCTURAL SOLAR MODULE AND CHASSIS

(71) Applicants: Bruce Khouri, Glendale, CA (US); Mustafa Pinarbasi, Morgan Hill, CA (US); Mark Ensor, San Jose, CA (US); Robert Campbell, Oakville (CA)

(72) Inventors: Bruce Khouri, Glendale, CA (US); Mustafa Pinarbasi, Morgan Hill, CA (US); Mark Ensor, San Jose, CA (US); Robert Campbell, Oakville (CA)

(73) Assignee: SoloPower, Inc., San Jose, CA (US)

(21) Appl. No.: 13/333,966

(22) Filed: Dec. 21, 2011

(51) Int. Cl. H01L 31/048

(52) U.S. Cl. 136/251

(57) ABSTRACT

A solar module having a curved surface to facilitate shedding of accumulated snow and water. The module can also be angled to achieve the same. The module includes a housing with a curved or angled upper surface and solar cells are positioned within the housing.

### RELATED APPLICATIONS

This application is related to U.S. application Ser. No. ______ (Atty Docket No. SPOW.001P1) entitled METHOD OF MANUFACTURING SOLAR MODULES.

### BACKGROUND

1. Field of the Inventions

The present inventions generally relate to solar panels and, more particularly, to design and manufacturing of solar panels including flexible thin film solar cells.

2. Description of the Related Art

Solar cells are photovoltaic (PV) devices that convert sunlight directly into electrical energy. Solar cells can be based on crystalline silicon or thin films of various semiconductor materials that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells offer improved cost advantages by employing deposition techniques widely used in the thin film industry. Group IBIIIAVIA compound photovoltaic cells, including copper indium gallium diselenide (CIGS) based solar cells, have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂ is formed on the conductive Mo film. The substrate 11 and the contact layer 12 form a base layer 13. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or a contact layer formed on the substrate as an absorber precursor, and are then reacted with S and/or Se in a high temperature annealing process.

After the absorber film 14 is formed, a transparent layer 15, for example, a CdS film, a ZnO film or a CdS/ZnO film-stack, is formed on the absorber film 14. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate, such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

Contrary to CIGS and amorphous silicon cells, which are fabricated on conductive substrates such as aluminum or stainless steel foils, standard silicon solar cells are not deposited or formed on a protective sheet. Such solar cells are separately manufactured, and the manufactured solar cells are electrically interconnected by a stringing or shingling process to form solar cell circuits. In the stringing or shingling process, the (+) terminal of one cell is typically electrically connected to the (−) terminal of the adjacent solar cell.

Interconnected solar cells may then be packaged in protective packages to form modules. Each module typically includes a plurality of solar cells which are electrically connected to one another. Many modules can also be combined to form large solar panels. The solar modules are constructed using various packaging materials to mechanically support and protect the solar cells in them against physical and chemical damage, especially against moisture. The most common packaging technology involves lamination of circuits in transparent layers. In a lamination process, in general, the electrically interconnected solar cells are first covered with a transparent and flexible encapsulant layer. A variety of materials are used as encapsulants, for packaging solar cell modules, such as ethylene vinyl acetate copolymer (EVA), thermoplastic polyurethanes (TPU), and silicones. However, in general, such encapsulant materials are moisture permeable; therefore, encapsulated cells are placed into an outer shell which further seal the solar cells from the environment and forms resistance to moisture transmission into the module. The outer shell typically includes a top transparent protective sheet and a bottom protective sheet sandwiching the encapsulated solar cells while exposing the light receiving front surface of the solar cells through the top transparent protective sheet. An edge sealant seals the periphery of the top and bottom protective sheets, thereby completing the module or panel construction. The top protective sheet is typically transparent glass which is water impermeable and the back protective sheet can be a glass sheet or a polymeric sheet with or without a moisture barrier layer, e.g., an aluminum film, in it. The top and bottom protective sheets are conventionally flat, which give the flat shape to the module, to expose the front surfaces of the solar cells to sun light.

In general, solar modules or panels are secured on rooftops, often on roof shingles or other varieties of rooftop structures, to directly expose them to unobstructed sunlight. However, flat glass top sheets of solar panels must provide enough strengths to meet snow load requirements. In order to meet this requirement, the manufacturers use thicker and stress- free or tempered flat glass sheets as the top protective sheet to protect the encapsulated sensitive solar cells. Although the added thickness improves the strength of the flat glass sheet, the weight associated with the increased thickness of the glass has its own drawbacks. One of the drawbacks is the high cost of installing such heavy panels on the rooftops, and possible high cost of rooftop modifications to prepare the rooftop for such heavy weight, especially when a plurality of panels are required. Such modifications may require penetrating installations to better anchor the heavy panels to the roof top, which can make the rooftop less weather resistant by disturbing the rooftop's original sealed structure. Furthermore, the heavy weight of such modules limits the deployment of them on the rooftops that cannot carry such heavy loads.

From the foregoing, there is a need for glass based solar panels providing enough strength with reduced weight that can be deployed in short time and reduced cost.

### SUMMARY

The aforementioned needs are satisfied by embodiments of the present invention which, in a solar module assembly comprises a solar module having a convexly curved or angled plate like body defined by a curved or angled transparent top layer of the solar module disposed over a curved or angled bottom layer of the solar module, wherein a plurality of solar cells are disposed between the curved or angled transparent top layer and the curved or angled bottom layer such that light receiving sides of the solar cells face the curved or angled transparent top layer; and a curved or angled support to retain the curved or angled solar module, the curved or angled support including a curved or angled support top surface that substantially contacts and conforms to the curved or angled bottom layer of the solar module.

The solar module may also comprise a plurality of solar cells and a solar module body having a top transparent layer and a bottom layer and first and second lateral edges, wherein the transparent layer and bottom layer define a space that receives the plurality of solar cells and wherein a portion of the top transparent layer is elevated with respect to the first and second lateral edges to facilitate snow and water sliding off of the top transparent layer towards the first and second lateral edges.

### BRIEF DESCRIPTION OF THE DRAWINGS

FIG. 1 is a schematic illustration of a solar cell;

FIG. 2 is a schematic illustration of a curved solar module supported by a curved module support;

FIG. 3 is a schematic cross-sectional illustration of the curved solar module shown in FIG. 2;

FIG. 4 is a schematic exploded view of a solar assembly embodiment including a curved solar module and an embodiment of a curved support frame;

FIG. 5 is a schematic frontal side view of the solar assembly installed on a surface;

FIG. 6 is a schematic illustration of an embodiment of attaching edges of the curved solar module to the curved support frame;

FIG. 7 is a schematic illustration of a front portion of the solar assembly after the edges of the curved module has been attached to the curved support frame ;

FIG. 8 is a schematic exploded view of another solar assembly embodiment including a curved solar module and another embodiment of a curved support frame;

FIG. 9 is a schematic frontal side view of the solar assembly installed on a surface;

FIG. 10 is a schematic illustration of an embodiment of attaching edges of the curved solar module to the curved support frame;

FIG. 11 is a schematic illustration of an angled solar module supported by an angled module support;

FIG. 12 is a schematic cross-sectional illustration of the angled solar module shown in FIG. 11; and

FIGS. 13A-14C are schematic illustrations of embodiments of a module assembly

### DETAILED DESCRIPTION OF THE PREFERRED EMBODIMENTS

The preferred embodiments described herein provide a solar module including a curved or angled module body or shell defined by a convexly curved or angled top transparent layer and a bottom layer which may be curved or angled and which may conform to the shape of the top transparent layer. The curved or angled transparent top layer is placed over the bottom layer, and a plurality of solar cells is disposed between the top transparent layer and the bottom layer. The plurality of solar cells includes a light receiving side facing the top transparent layer. Curvature or angling of the module provides structural strength to the module without increasing its weight, thereby allowing maximum snow load and facilitating shedding of water, snow or other precipitation. In another embodiment of the present invention a solar module assembly including the convexly curved or angled module and a curved or angled support frame to retain the solar module is provided. In one embodiment, the curved or angled support frame may include a curved or angled top surface that substantially contacts and conforms to the curved or angled bottom layer of the solar module. The solar module assembly may further include attachment elements or feet on the opposite side of the curved or angled top surface of the curved or angled support frame to install the solar module assembly on an application surface such as a rooftop. The curved or angled support frame provides the module structural integrity by mechanically supporting it. The curved or angled shape of the support elevates the module off the rooftop, thereby allowing air flow beneath the curved or angled module, which optimizes module's thermal performance by acting as a cooling source.

FIG. 2 shows an exemplary solar module assembly 90 of the present invention including a solar module 100 supported by a support 102. The solar module includes a plurality of solar cells 105 depicted with dotted lines in FIG. 2. The solar module has a convexly curved body that may be curved along a longitudinal axis ‘L’, or L-axis, of the solar module 100. In one embodiment, the curved body of the solar module 100 may be a curved rectangular body that extends along the L-axis such that long edges 104A of the solar module 100 extend parallel to the L-axis and between curved edges 104B which may have the same curvature. In this embodiment, the module is held and supported by the support 102 which is also convexly curved and extending along the L-axis of the curved module and thus conforms to the convexly curved shape of the solar module 100. The support 102 may be a continuous support comprising a single support surface extending and covering the full bottom surface of the curved solar module 100 or a discontinuous support comprising a number of integrated support surfaces supporting the full bottom surface of the curved solar module at selected bottom surface sections. In one implementation, the long edges 104A and the curved edges 104B of the solar module are aligned with long edges 106A and curved edges 106B of the support 102 respectively as in the manner shown in FIG. 2. As will be described more fully below, depending on the use, the design and structure of the support 102 may vary.

FIG. 3 shows a detail view of the convexly curved cross section of the solar module 100 shown in FIG. 2. In this view the L-axis is perpendicular to the plane of the paper or parallel to the y-axis of the 3-D coordinate system shown in FIG. 3. It is understood that the structure of module 100 is examplary and demonstrative and is drawn for the purpose of showing various aspects of the present inventions. As also shown in FIG. 2, the module 100 comprises examplary solar cells 105 which may be electrically interconnected in series using conductive leads (not shown). It is possible that the solar cells 105 may be shingled and, therefore, there may be no conductive leads interconnecting them. The solar cells may be flexible solar cells or curved solar cells which may have a curvature complying with the curvature of the module. The interconnected cells are connected to a junction box located outside the module 100. The junction box may be located in or be an integral part of the support 102. The electrically interconnected solar cells or so called solar cell strings are covered with a transparent and flexible encapsulant layer 110 which fills any hollow space among the cells and tightly seals them, preferably covering both of their surfaces. A variety of materials are used as encapsulants for packaging solar cell modules such as ethylene vinyl acetate copolymer (EVA) and thermoplastic polyurethanes (TPU). The encapsulated solar cells are further sealed from the environment by a protective shell 112, which forms a barrier against moisture transmission into the module package. The protective shell of the module includes a top transparent layer 114 or top transparent sheet and a bottom layer 116 or bottom sheet and an edge sealant 118 extending between the top protective sheet and the bottom protective sheet. The water vapor transmission rate of the edge a sealant is preferably below 0.001 gm/m²/day, more preferably below 0.0001 gm/m²/day.

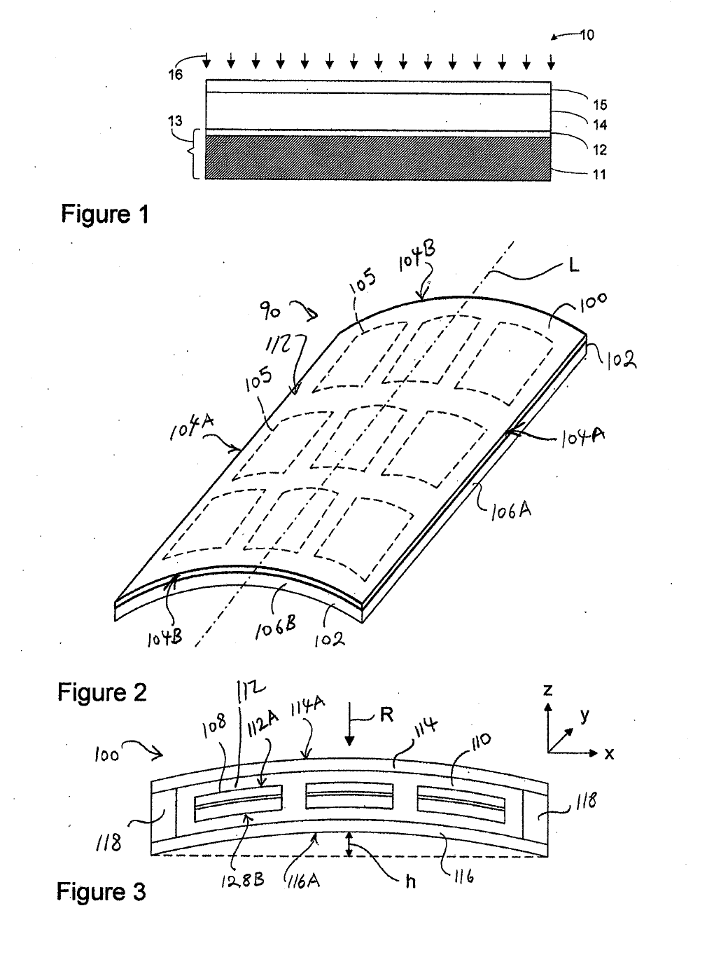

In the module 100, each solar cell 105 includes a front light receiving side 119A facing toward the top transparent layer 114 and a back side 128B facing towards the bottom layer 116 of the module. The solar cells 105 may be conventional CIGS based thin film solar cells, which are exemplified in FIG. 1. The front light receiving side 119A includes an absorber layer and a transparent layer deposited over the absorber layer. The absorber layer may be a Group IBIIIAVIA compound semiconductor layer such as a Cu (Ga, In) (Se, S)₂ thin film or CIGS. The transparent layer may include a stack including a buffer layer such as a CdS layer deposited over the absorber layer and a transparent conductive oxide (TCO) layer such as a ZnO layer deposited over the buffer layer. The back side 128B of each solar cell 105 includes a substrate and a contact layer.

Referring back to FIG. 3, in one embodiment, the top transparent layer 114 and the bottom layer 116 of the module 100 have a convexly curved shape. As shown in FIG. 3, the top transparent layer 114 is placed over the bottom layer 116 which conforms to the curvature of the top transparent layer. The distance between the top transparent layer 114 and the bottom layer 116 does not change throughout the module body; therefore the radial distance formed between a top outwardly curved surface 114A and a bottom inwardly curved surface 116A of the module 100 is the same predetermined distance or the thickness of the module 100. In one embodiment, the convexly curved top transparent layer and the bottom layer may be shaped as an arc having an arc-height, or arc-depth, from 10 mm to 200 mm from peak of arc to the midpoint perpendicular to chord of the arc shown in dotted lines in FIG. 3. The arc of the curved edges 106B of the support 102 shown in FIG. 2 may also have the same arch-height ‘h’.

In one implementation, the top transparent layer 114 having the desired convexly curved shape may be a curved glass layer or sheet, such as a tempered glass sheet, or it may also be a curved transparent flexible polymer film such as TEFZEL® from DuPont, polyethylene terephthalate (PET), polyethylene naphthalate (PEN) or another polymeric film with moisture barrier coatings. The bottom layer 116 may be a curved sheet of glass or a curved polymeric sheet such as TEDLAR®, or another polymeric material which may or may not be transparent.

In another embodiment, the module 100 may have a flexible flat body made of the above exemplified flexible polymer sheets. The convexly curved shape of the flexible module is formed when the flexible module is applied and retained on the curved support, for example, as shown in FIG. 2. For both embodiments, the curvature of the module 100 provides multiple functions including but not limited to structural rigidity, elevation, cooling, show loading, water shedding, water flow through, air flow disruption, junction box and cable UV shielding.

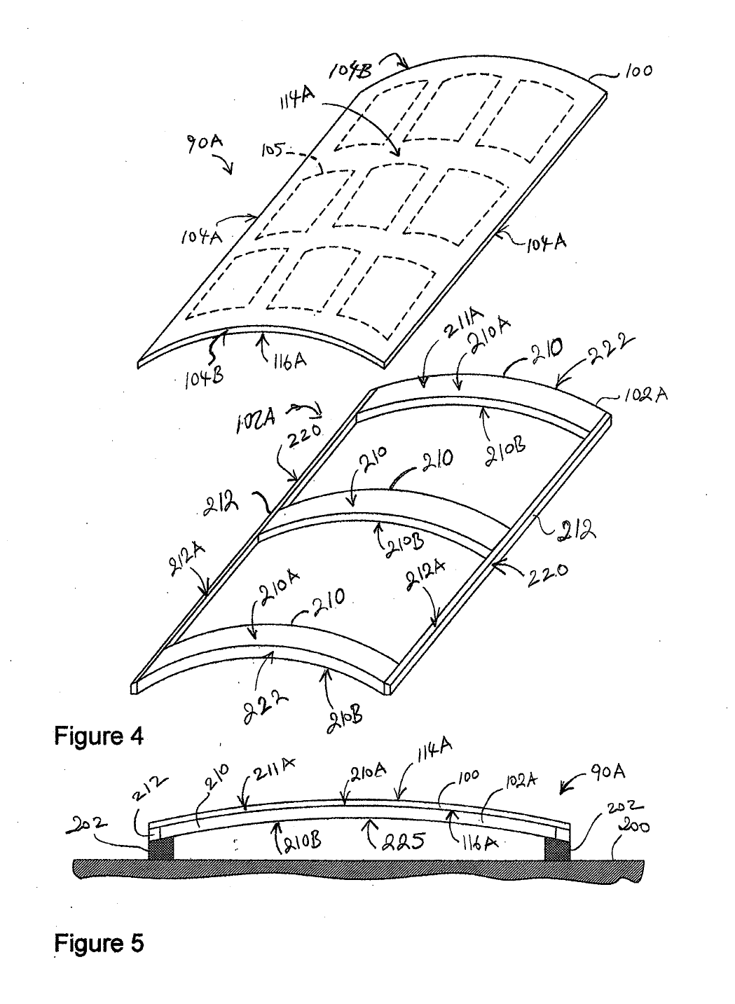

FIGS. 4 through 10 show various solar module assembly embodiments employing the module 100 described above and various support embodiments. As shown in FIG. 4 in an exploded view, an embodiment of a solar module assembly 90A includes the curved solar module 100 described in FIGS. 2 and 3 and a support frame 102A or chassis. FIG. 5 shows a frontal view of the assembly when installed on an application surface 200 such as rooftop using attachment members 202 or feet.

The support frame 102A of the module assembly 90A includes a number of curved cross members 210 attached to at least two side members 212. The curved cross members 210 are curved sheet like strips with a desired thickness, each having curved top surface 210A and curved back surface 210B. The side and curved cross members may be made of metals (such as aluminum) or plastics (such as polycarbonates) adequate for long-term use and resistant to conditions prevalent in outdoor environments. Such conditions could be, but are not limited to, extreme temperature variations, mechanical stress caused by expansion and contraction of the module and chassis components due to temperature variations, exposure to the sun, exposure to fire, exposure to high loads such as caused by wind, rain, snow, hail, and installation, transportation, and repair handling. Cross members may be designed with sufficient thickness, such as +/−25 mm, to provide room for junction boxes (if applicable) such that solar panels can be stacked flat during shipping to maximize the number of panels that can be shipped at one time. Widths and lengths of cross members may be adjusted as appropriate for the length, width, and weight of module.

As shown in FIG. 5, in one implementation, three curved cross members 210, which may preferably be spaced equidistantly, extend between the side members 212. The side members extend parallel to the L-axis of the module 100. In this configuration, both the upper surfaces 210A of the curved cross members 210 and upper surfaces 212A of the side members 212 define a substantially discontinuous curved support surface 211 A that the inwardly curved surface 116A of the curved module 100 conforms to. The support frame 102A provides a mechanically secure platform to deploy large curved modules onto residential and commercial/industrial rooftops. The support frame 102A is shaped and dimensioned to match the shape of the curved solar module 100, and when they are assembled together as in the manner shown in FIG. 5, the long edges 104A and the curved edges 104B of the curved solar module 100A may be aligned with long edges 220 and curved edges 222 of the support frame 102A, respectively. Exposed surface portions of the bottom inwardly curved surface 116A and the bottom surfaces 210B of the curved cross members 210 define a curved bottom wall 225 of the module assembly 90A. Due to its curved shape, the curved bottom wall 225 of the module assembly is elevated from the application surface and defines a large tunnel-like passage under the assembly. Such space allows air to flow under the assembly 90A to optimize the temperature of the module 100 held by the assembly. To increase the mechanical stability of the module assembly 90A, the attachment members 202 or feet may be secured to the side support members 212 at locations where the ends of the curved cross members 210 join to the side support members.

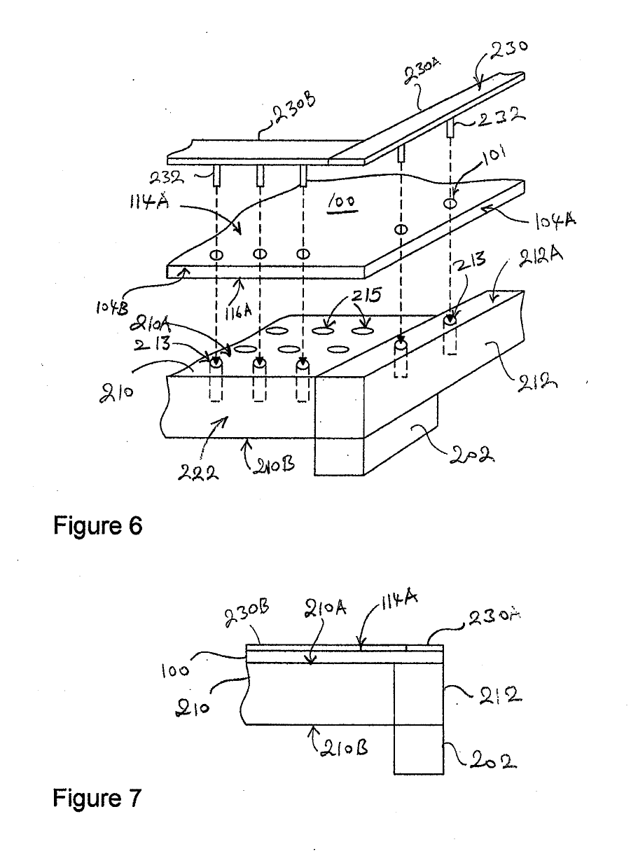

In the module assembly 90A, the curved solar module 100 can be attached to the support frame 102A using various fastening and bonding methods. As shown in FIG. 6 in a partial exploded view and in FIG. 7 in side view, in one embodiment, the curved support frame 102A includes first holes 213 formed vertically along the perimeter of the support frame in the side members 212 and the curved cross members 210. The curved support frame may optionally include second holes 215 or adhesive holes formed in the upper surface 210A of the curved cross members 210. The first holes 213 engage with module edge holders 230 or edge rail to capture or retain the perimeter of the solar module 100. There may be two side edge holders 230A to secure both long edges 104A of the module on both side members 212, and there may be two cross edge holders 230B to secure the curved edges 104B of the module on both curved cross members 210. For this purpose, an edge region of the module may include edge holes 101 formed adjacent the long edges 104A and the curved edges 104B. It is important that the edge holes 101 of the curved module 100 be formed without damaging the edge moisture sealant and preferably through an extended edge portion (not shown) of the curved module 100.

In one embodiment, to attach the curved module 100 onto the curved support frame 102A, firstly, if they are used, the second holes 215 may be filled with an adhesive and the curved module 100 is pressed against the adhesive filling the holes to attach and secure the body of the module 100 on the curved support frame 102A; secondly, pins 232 of the edge holder 230 are passed through the edge holes 101 of the curved module 100 and inserted into the first holes 213 to secure the edges 104A, 104B of the curved module 100. The pins 232 and the first holes 213 may have mating features to interlock and keep the pins 232 in the first holes 213, and thereby allowing the module edge holder to secure the edges 104A, 104B of the module on the support frame 102A. A strip 233 or clip portion of the module edge holder 230 seals the first holes 213 and further restrains the module edges on the support.

In an alternative embodiment, there may be used only two side edge holders 230A without the cross edge holders 230B. In this alternative approach, the adhesive holes including the adhesive may or may not be used. Holes or slots and pins are to be sized appropriate for resistance to environmental and mechanical loads stated previously and the material strengths of pin material and module materials. One such size is +/−5 mm diameter but the size is not limited to this. Adhesives, if used, provide resistance to water egress into the module materials and be resistant to the environmental conditions into which they will be exposed. Such materials are, but are not limited to Butyl based and Silicon based materials.

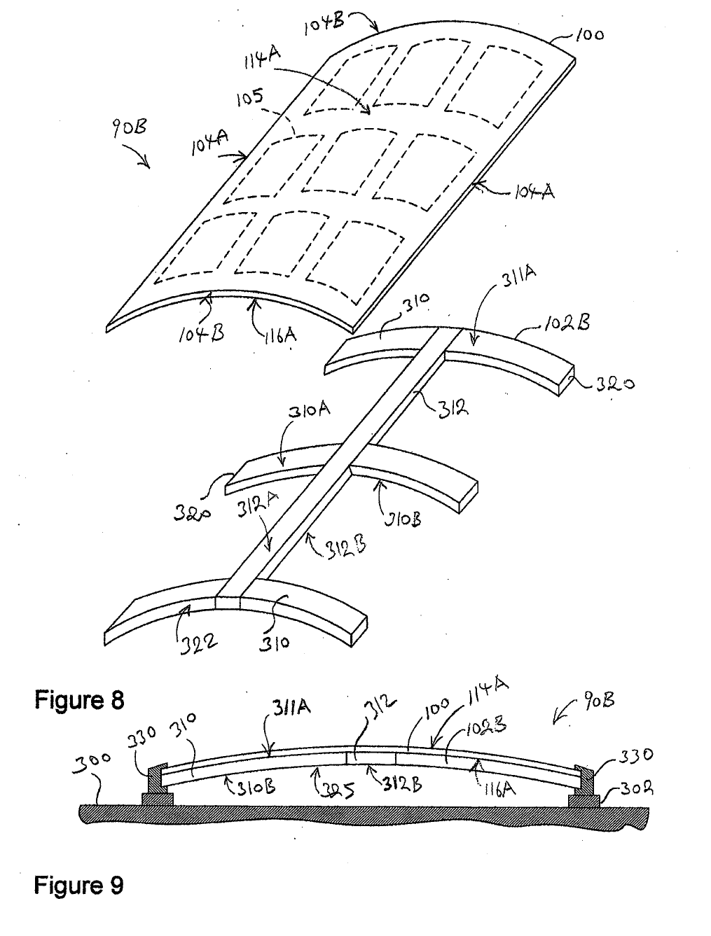

FIG. 8 shows in exploded view, another embodiment of a solar module assembly 90B including the curved solar module 100 described in FIGS. 2 and 3 and another support frame 102B or chassis. FIG. 9 shows a frontal view of the assembly when installed on an application surface 300 such as rooftop using attachment members 302 or feet.

The support frame 102B of the module assembly 90B includes a number of curved support members 310 or ribs attached to a center support member 312. The center support member 312 extends along the length of the curved solar module 100 and the plurality of attached support members extend outwardly in opposite directions from the center support member 312 so that both the upper sides of the center support member 312 and curved support members 310 define an elongated convex frame surface. The curved support members 310 are curved sheet like strips with desired thickness and each having a curved top surface 310A and a curved back surface 310B. As shown in FIG. 8, in one implementation, six curved support members 310, which may preferably be spaced equidistantly, extend from the center support member 312 such that both the upper surfaces 310A of the curved support members 310 and upper surface 312A of the center member 312 define a substantially discontinuous curved support surface 311 A that the inwardly curved surface 116A of the curved module 100 conforms to. The support frame 102B provides a mechanically secure platform to deploy large curved modules onto residential and commercial/industrial rooftops as in the previous embodiment. The side and curved cross members may be made of metals (such as aluminum) or plastics (such as but not limited to polypropylenes or polycarbonates reinforced with glass fibers, UV and fire resistant additives) adequate for long-term use and resistant to conditions prevalent in outdoor environment. Cross members may be designed with sufficient thickness, such as +/−25 mm, to provide room for junction boxes (if applicable) such that solar panels can be stacked flat during shipping to maximize the number of panels that can be shipped at one time. Widths and lengths of cross members may be adjusted as appropriate for the length, width, and weight of module.

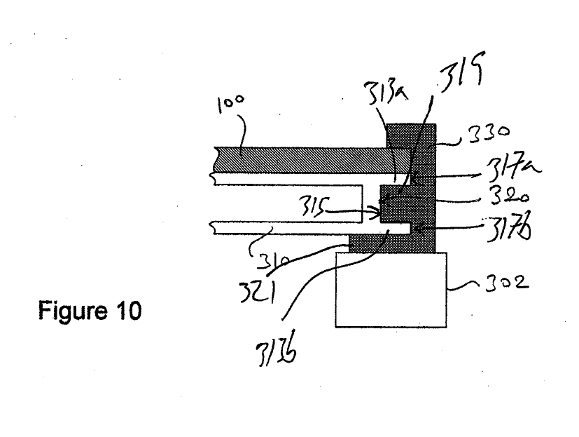

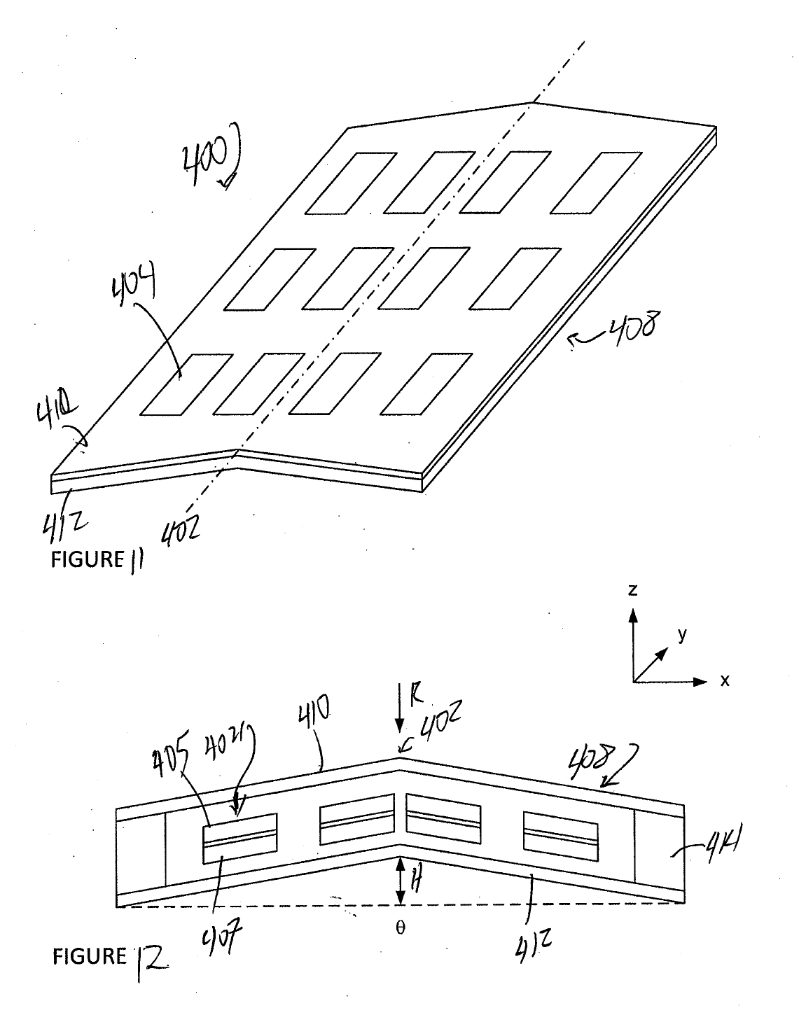

The support frame 102B is shaped and dimensioned to match the shape of the curved solar module 100, and when they are assembled together as in the manner shown in FIG. 5, long edges 104A and the curved edges 104B of the curved solar module 100 may be aligned with outer ends 320 and curved edges 322 of the support frame 102B, respectively. Further, exposed surface portions of the bottom inwardly curved surface 116A, the bottom surfaces 310B of the curved support members 310 and a bottom surface 312B of the center support member 312 define a curved bottom wall 325 of the module assembly 90B. Due to the its curved shape, the curved bottom wall 325 of the module assembly is elevated from the application surface and defines a large tunnel-like passage under the assembly. Such space allows air to flow under the module assembly 90B to regulate the temperature of the module 100 held by the assembly. To increase the mechanical stability of the module assembly 90B, the attachment members 302 or feet may be secured to the outer end 320 of curved support members 312. As shown in FIG. 10, in one embodiment, retainer members 330 are used with the attachment members 302 to hold the ends 320 of the curved support members 310 and the long edges 104A of the curved solar module 100 so as to hold the curved solar module 100 in engagement with the support frame 102B.

More specifically, as shown in FIG. 10, the curved support member 310 has two arms 313a, 313b that form an “H” shape and define an opening 315. The retainer member 330 includes two apertures 317a, 317b that receive the arms 313a, 313b and a protrusion 319 that extends into the opening 315. In this implementation, the retainer member 330 also includes a bottom support member 321 that extends past the H-shaped arms 313a, 313b and is interposed between the curved support member 310 and the attachment member 320. In this way, the curved support member 310 and the panels can thus be securely mounted. It will be appreciated that any of a number of different mounting structures can be used without departing from the spirit and scope of the present invention.

It will be appreciated that the solar module assembly can also be angled as opposed to curved in the manner shown in FIGS. 1-10. More specifically, as shown in FIGS. 11 and 12, the solar module 400 is preferably angled about a center axis 402. As discussed in greater detail below, the angle θ about the center axis 402 is selected so as to provide an angled surface to facilitate snow and water removal but still allow solar cells 404 to be exposed to the sun. In this implementation, the solar module 400 includes solar cells 404 having a substrate 405 and an absorber layer 407 that do not have to be curved but can be formed so as to be straight in the manner shown in FIG. 1. The solar cells 404 are encapsulated within the module 400 and have a protective shell 408 in the same manner having an upper transparent layer 410, a bottom surface 412, and side seals 414 as described above and is positioned on an angled support frame (not shown) that is similar to the curved support described above.

In both the curved and angled implementations, the center portion of the module is raised above the outer edges of the module by an amount h selected to provide a sufficient angle to facilitate snow and water running off of the panel while still allowing the solar cells to be directly exposed to the sunlight. It will be appreciated that one side of the solar panel will be directly facing the sun and the other curved or angled side will not be directly facing the sun. However, if the curvature or angling is not large enough to cause the solar panels to be shaded, the efficiency of the solar cells that are not directly facing the sun is not significantly diminished. The Applicant has determined that an angle within the range of approximately 2 degrees to 30 degrees or a radius of curvature within the range of approximately 2.2 meters to 7 meters provide a surface that is capable of shedding snow and water due to gravity which thereby enhances the efficiency of the solar module but does not significantly impact the solar efficiency of the cells that are not directly facing the sun.

It will be further appreciated that any of a number of different configurations of the module can be made that facilitate snow or water drainage from the solar module. So long as a center portion of the module is elevated with respect to the edges, the solar module can thus facilitate water removal while still permitting the solar cells within the module to directly receive sunlight. Thus, the center portion can be raised with respect to the edges by curving the module or angling the module in the manner described above.

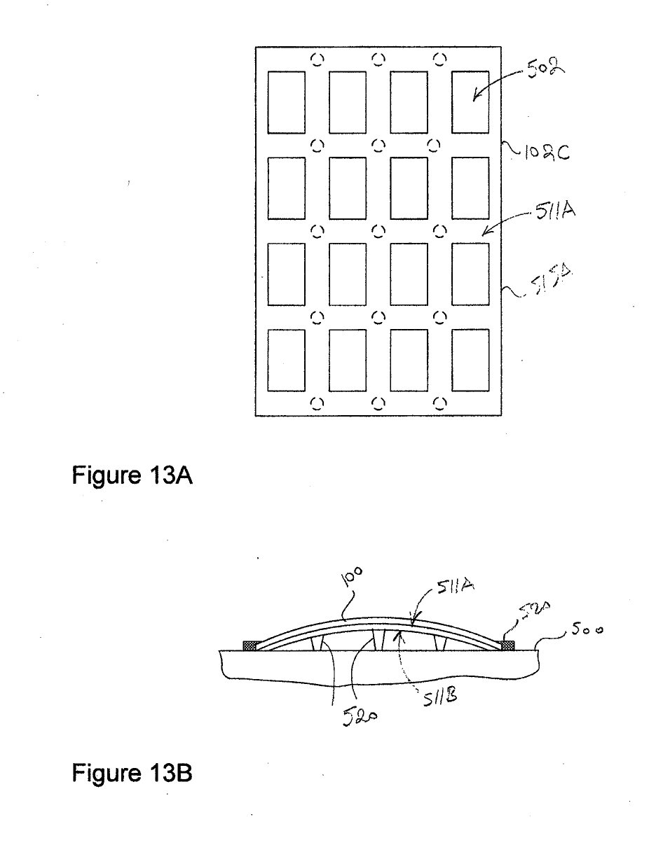

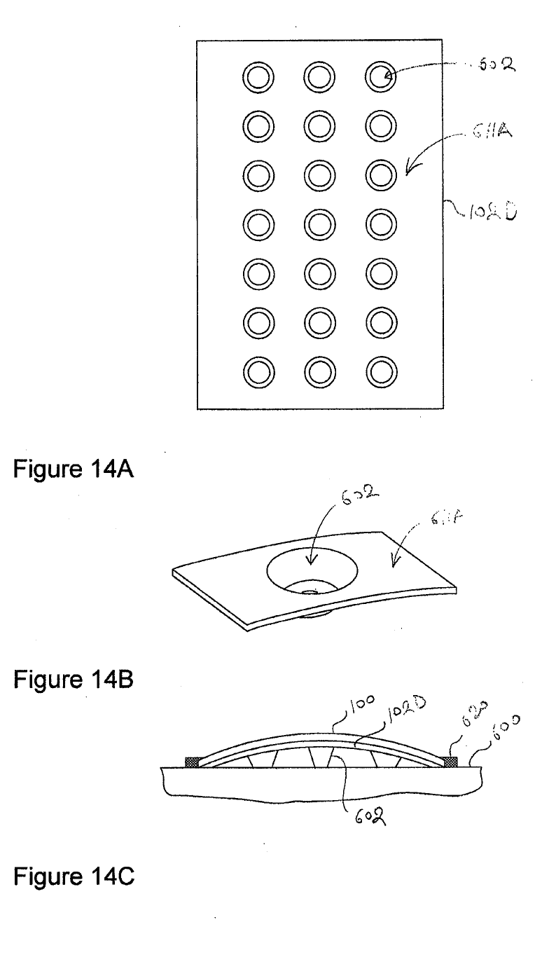

FIGS. 13A-14C show alternative curved support frame embodiments to retain the module 100 as described in the above curved module assembly embodiments. In these embodiments straight edges of the curved support frame may rest directly on the application surfaces without needing any additional feet or other support. The module on the support frame may be held by the retainer members secured on the application surfaces. The module may not be physically attached to the underlying support frame but may use it as a saddle. Alternatively, the module may be attached to the support frame as in the previous embodiments, and the support frame may be attached to the application surface. FIG. 13A shows a curved support frame 102C in top view, and FIG. 13B shows the curved support frame 102C assembled with the solar module 100 in frontal side view. The curved support frame 102C includes a number of openings 502 extending between a curved upper surface 511A or support surface and a curved bottom surface 511B. The openings 502 provide air flow for the module. In this embodiment the curved support frame 102C is supported on an application surface 500 by a plurality of legs 511 as well as long edges 515A that rest on the application surface 500. The legs 511 extend from the curved back surface 511B, and the long edges 515A of the of the support frame 102C are tapered to conform to the flat application surface. In one embodiment, the assembly may be held on the application surface 500 by capturing the long edges 515 of the module with retainer members 520, such as clamps, braces or fasteners secured on the application surface which securely hold the edges of the module supported by the support frame, and thereby securing the module assembly on the application surface.

FIG. 14A shows another curved support frame 102D in top view, and FIG. 14C shows the curved support frame 102D assembled with the solar module 100 in frontal side view. The curved support frame 102D includes a number of recesses 602 that function as legs for the curved support frame 102D while providing air circulation. As shown in FIG. 14B the recess 602 may have a round or cup shape formed in the upper curved surface 611A and may have an opening at the bottom. The curved support frame 102D is supported on an application surface 500 by both the recesses 602 and long edges 615A that rest on the application surface 500. The long edges 615A of the of the support frame 102D may also be tapered to conform to the flat application surface. As in the previous embodiment, the module-support frame assembly may be held on the application surface 600 by capturing the long edges 515 of the module with retainer members 520, such as clamps, braces or fasteners secured on the application surface which securely hold the edges of the module supported by the support frame, and thereby securing the module assembly on the application surface.

Although aspects and advantages of the present inventions are described herein with respect to certain preferred embodiments, modifications of the preferred embodiments will be apparent to those skilled in the art. Thus the scope of the present inventions should not be limited to the foregoing discussion, but should be defined by the appended claims.

What is claimed is:

1. A solar module assembly, comprising:
a solar module having a convexly curved or angled plate like body defined by a curved or angled transparent top layer of the solar module disposed over a curved or angled bottom layer of the solar module, wherein a plurality of solar cells are disposed between the curved or angled transparent top layer and the curved or angled bottom layer such that light receiving sides of the solar cells face the curved or angled transparent top layer; and
a curved or angled support to retain the curved or angled solar module, the curved or angled support including a curved or angled support top surface that substantially contacts and conforms to the curved or angled bottom layer of the solar module.

2. The solar module assembly of claim 1, wherein the solar module is curved or angled along a longitudinal axis of the solar module.

3. The solar module assembly of claim 2, wherein the curved or angled support extends along the longitudinal axis of the solar module.

4. The solar module assembly of claim 1, wherein the curved or angled support top surface is defined by a continuous curved top surface of a continuous support member.

5. The solar module assembly of claim 1, wherein the curved or angled support top surface is defined by a substantially discontinuous curved surface formed by top surfaces of a plurality of support members.

6. The solar module assembly of Claim, 5 wherein the plurality of support members includes at least two curved cross members extending between and secured to two side members.

7. The solar module assembly of Claim, 5 wherein the plurality of support members includes a center member and at least two curved rib members attached to and extending outwardly in opposite directions from the center member.

8. The solar module assembly of Claim, 1 further including retainer members to cooperate between the ends of a curved or angled support and the edges of the solar module to hold the solar module in engagement with the curved or angled support.

9. The solar module assembly of Claim, 1 further including attachment elements on the opposite side of the curved or angled support top surface to install the solar module assembly on an application surface.

10. The solar module assembly of claim 1, wherein the attachment elements further include interlocking members shared by adjacent solar module assemblies.

11. The solar module assembly of claim 1, wherein the curved or angled top layer of the module is one of a tempered glass and polymer.

12. The solar module assembly of claim 1, wherein the curved or angled support is made of a polymer material.

13. The solar module assembly of claim 2, wherein the solar module comprises a convexly curved or angled plate like body that has an arc shaped cross section extending along the longitudinal axis.

14. The solar module assembly of claim 2, wherein the curved or angled support has an arc shaped cross section extending along the longitudinal axis.

15. The solar module assembly of claim 13, wherein the arc shaped cross section has a height in the range of 10 mm to 200 mm from peak of arc to the midpoint perpendicular to chord of the arc.

16. The solar module assembly of claim 14, wherein the solar cells are CIGS based solar cells.

17. The solar module assembly of claim 14, wherein the solar cells are flexible solar cells.

18. The solar module assembly of claim 14, wherein the solar cells are curved solar cells.

19. A solar module comprising:
a plurality of solar cells;
a solar module body having a top transparent layer and a bottom layer and first and second lateral edges, wherein the transparent layer and bottom layer define a space that receives the plurality of solar cells and wherein a portion of the top transparent layer is elevated with respect to the first and second lateral edges to facilitate snow and water sliding off of the top transparent layer towards the first and second lateral edges.

20. The module of claim 19, wherein the plurality of solar cells are CIGS based solar cells.

21. The module of claim 19, wherein the solar module body is curved and has a curved top transparent layer.

22. The module of claim 19, wherein the radius of curvature of the solar module body is within the range of approximately 2.2 m to approximately 7.0 m.

23. The module of claim 22, wherein the plurality of solar cells are curved with a radius of curvature that corresponds to the radius of curvature of the solar module body.

24. The module of claim 22, wherein the curved top transparent layer defines a continuous curved top surface.

25. The module of claim 22, wherein the curved top transparent layer defines a substantially discontinuous curved top surface.

26. The module of claim 19, wherein the solar module body is angled about an angle defined by a central portion of the solar module body.

27. The module of claim 26, wherein the solar module body is angled at an angle that falls substantially within the range of approximately 2° to approximately 30°.
